(19) United States
(12) Patent Application Publication
(10) Pub. No.: US 2022/0093426 A1
(43) Pub. Date: Mar. 24, 2022

(54) MOVABLE SEMICONDUCTOR PROCESSING CHAMBER FOR IMPROVED SERVICEABILITY

(71) Applicant: Applied Materials, Inc., Santa Clara, CA (US)

(72) Inventors: Samuel W. Shannon, San Jose, CA (US); Luke Bonecutter, Cedar Park, TX (US); Viren Kalsekar, Mountain View, CA (US); Chahal Neema, Mountain View, CA (US)

(73) Assignee: Applied Materials, Inc., Santa Clara, CA (US)

(21) Appl. No.: 17/026,862

(22) Filed: Sep. 21, 2020

(51) Int. Cl. H01L 21/67; H01J 37/32

(52) U.S. Cl. CPC H01L 21/67196; H01L 21/67126; H01L 21/68707; H01L 21/67167; H01J 37/32733

(57) ABSTRACT

Exemplary substrate processing systems may include a base. The systems may include a chamber body having a transfer region housing that defines a transfer region. The transfer region housing may include a first portion and a second portion. The systems may include a lid assembly positioned atop the chamber body. The lid assembly may include a lid and a lid stack. The systems may include one or more lift mechanisms that elevate the first portion of the transfer region housing and at least a portion of the lid assembly relative to the base. The first portion and the second portion may mate with one another when the transfer region housing is in an operational configuration. The first portion and the second portion may be separated when the first portion of the transfer region housing is elevated.

### TECHNICAL FIELD

The present technology relates to semiconductor processes and equipment. More specifically, the present technology relates to substrate processing systems and methods of substrate processing.

### BACKGROUND

Semiconductor processing systems often utilize cluster tools to integrate a number of process chambers together. This configuration may facilitate the performance of several sequential processing operations without removing the substrate from a controlled processing environment, or it may allow a similar process to be performed on multiple substrates at once in the varying chambers. These chambers may include, for example, degas chambers, pretreatment chambers, transfer chambers, chemical vapor deposition chambers, physical vapor deposition chambers, etch chambers, metrology chambers, and other chambers. The combination of chambers in a cluster tool, as well as the operating conditions and parameters under which these chambers are run, are selected to fabricate specific structures using particular process recipes and process flows.

Cluster tools often process a number of substrates by continuously passing substrates through a series of chambers and process operations. The process recipes and sequences will typically be programmed into a microprocessor controller that will direct, control, and monitor the processing of each substrate through the cluster tool. Once an entire cassette of wafers has been successfully processed through the cluster tool, the cassette may be passed to yet another cluster tool or stand-alone tool, such as a chemical mechanical polisher, for further processing.

Robots are typically used to transfer the wafers through the various processing and holding chambers. The amount of time required for each process and handling operation has a direct impact on the throughput of substrates per unit of time. Substrate throughput in a cluster tool may be directly related to the speed of the substrate handling robot positioned in a transfer chamber. As processing chamber configurations are further developed, conventional wafer transfer systems may be inadequate.

Thus, there is a need for improved systems and methods that can be used to efficiently direct substrates within cluster tool environments. These and other needs are addressed by the present technology.

### SUMMARY

Exemplary substrate processing systems may include a base. The systems may include a chamber body having a transfer region housing that defines a transfer region. The transfer region housing may include a first portion and a second portion. The systems may include a lid assembly positioned atop the chamber body. The lid assembly may include a lid and a lid stack. The systems may include one or more lift mechanisms that elevate the first portion of the transfer region housing and at least a portion of the lid assembly relative to the base. The first portion and the second portion may mate with one another when the transfer region housing is in an operational configuration. The first portion and the second portion may be separated when the first portion of the transfer region housing is elevated.

In some embodiments, an interface between the first portion and the second portion may include a sealing element that seals an interior of the transfer region housing when the transfer region housing is in the operational configuration. An interface between the first portion and the second portion may include a radio frequency gasket. At an interface between the first portion and the second portion, faces of each of the first portion and the second portion may be angled relative to vertical. An angle of the faces of each of the first portion and the second portion may be between about 10 degrees and about 80 degrees relative to vertical. One of the first portion and the second portion may include one or more alignment pins and the other of the first portion and the second portion may define one or more apertures that receive the one or more alignment pins when the first portion and the second portion are in the operational configuration. Each of the one or more apertures may be lined with a bushing. The transfer region housing and the at least the portion of the lid assembly may be elevatable independently of one another by the one or more lift mechanisms. The one or more lift mechanisms may include a worm gear lift that is driven by a rotational actuator. The systems may include a frame that is coupled with each of the base, the chamber body, and the lid assembly. A top of the frame may telescope between a first height and a second height.

Some embodiments of the present technology may encompass substrate processing systems including a base. The systems may include a chamber body having a transfer region housing that defines a transfer region. The transfer region housing may include a first portion and a second portion. The systems may include a lid assembly positioned atop the chamber body. The lid assembly may include a lid and a lid stack. The systems may include one or more lift mechanisms that at least a portion of the lid assembly relative to the base. The systems may include a slide that slides the first portion of the transfer region housing at least partially out of vertical alignment with the lid assembly and the base. The first portion and the second portion may mate with one another when the transfer region housing is in an operational configuration. The first portion and the second portion may be separated when the first portion of the transfer region housing is slid at least partially out of vertical alignment with the lid assembly and the base.

In some embodiments, at an interface between the first portion and the second portion, faces of each of the first portion and the second portion may be vertical. At an interface between the first portion and the second portion, faces of each of the first portion and the second portion may be angled relative to vertical. An interface between the first portion and the second portion may include a sealing element that seals an interior of the transfer region housing when the transfer region housing is in the operational configuration. The systems may include a frame coupled with the base. The slide may include a roller track assembly that slidingly couples the first portion of the transfer region housing with the frame. The systems may include a frame that may be coupled with each of the base, the chamber body, and the lid assembly. A top of the frame may telescope between a first height and a second height. One of the first portion and the second portion may include one or more alignment pins and the other of the first portion and the second portion may define one or more apertures that receive the one or more alignment pins when the first portion and the second portion are in the operational configuration. One of a top surface of the chamber body and a bottom surface of the lid assembly may include one or more alignment pins and the other of the top surface and the bottom surface may define one or more apertures that receive the one or more alignment pins when the lid assembly is positioned atop the chamber body.

Some embodiments of the present technology may encompass methods of providing access to an interior of a substrate processing system. The methods may include elevating, using one or more lift mechanisms, at least a portion of a lid assembly of a substrate processing system relative to a base of the substrate processing system. The lid assembly may include a lid and a lid stack. The methods may include moving a first portion of a transfer region housing of a chamber body of the substrate processing system out of engagement with a second portion of the transfer region housing in a vertical direction or a horizontal direction to provide access to the interior of the substrate processing system. The first portion and the second portion may mate with one another when the transfer region housing is in an operational configuration. In some embodiments, the first portion of the transfer region housing is moved in the vertical direction in unison with elevation of the lid.

Such technology may provide numerous benefits over conventional systems and techniques. For example, the processing systems may provide repeatable and self-aligning movement of various system components to facilitate easier servicing of interior components. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1A shows a schematic top plan view of an exemplary processing system according to some embodiments of the present technology.

FIG. 1B shows a schematic partial cross-sectional view of an exemplary chamber system according to some embodiments of the present technology.

FIG. 2 shows a schematic isometric view of a transfer region of an exemplary chamber system according to some embodiments of the present technology.

FIGS. 3A-3C show schematic side elevational views of an exemplary chamber system according to some embodiments of the present technology.

FIG. 3D shows a schematic plan view of an exemplary mating face of a transfer region housing according to some embodiments of the present technology.

FIG. 4 shows a schematic side elevational view of an exemplary processing system according to some embodiments of the present technology.

FIG. 5 shows operations of an exemplary method of providing access to an interior of a substrate processing system according to some embodiments of the present technology.

Several of the figures are included as schematics. It is to be understood that the figures are for illustrative purposes, and are not to be considered of scale or proportion unless specifically stated to be of scale or proportion. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

Substrate processing can include time-intensive operations for adding, removing, or otherwise modifying materials on a wafer or semiconductor substrate. Efficient movement of the substrate may reduce queue times and improve substrate throughput. To improve the number of substrates processed within a cluster tool, additional chambers may be incorporated onto the mainframe. Although transfer robots and processing chambers can be continually added by lengthening the tool, this may become space inefficient as the footprint of the cluster tool scales. Accordingly, the present technology may include cluster tools with an increased number of processing chambers within a defined footprint. To accommodate the limited footprint about transfer robots, the present technology may increase the number of processing chambers laterally outward from the robot. For example, some conventional cluster tools may include one or two processing chambers positioned about sections of a centrally located transfer robot to maximize the number of chambers radially about the robot. The present technology may expand on this concept by incorporating additional chambers laterally outward as another row or group of chambers. For example, the present technology may be applied with cluster tools including three, four, five, six, or more processing chambers accessible at each of one or more robot access positions.

However, as additional process locations are added, accessing these locations from a central robot may no longer be feasible without additional transfer capabilities at each location. Some conventional technologies may include wafer carriers on which the substrates remain seated during transition. However, wafer carriers may contribute to thermal non-uniformity and particle contamination on substrates. The present technology overcomes these issues by incorporating a transfer section vertically aligned with processing chamber regions and a carousel or transfer apparatus that may operate in concert with a central robot to access additional wafer positions. The present technology may not use conventional wafer carriers in some embodiments, and may transfer specific wafers from one substrate support to a different substrate support within the transfer region.

Due to the heavy weight of the components of such systems, servicing of processing systems with such small footprints, moving the lid, lid stack, and/or transfer section to gain access to other components may be difficult. To address these concerns, embodiments of the present technology may incorporate lift and/or slide mechanisms that enable repeatable and self-aligning movement of the various components to provide access and clearance for servicing interior components of the processing system.

Although the remaining disclosure will routinely identify specific structures, such as four-position transfer regions, for which the present structures and methods may be employed, it will be readily understood that the systems and methods are equally applicable to any number of structures and devices that may benefit from the transfer capabilities explained. Accordingly, the technology should not be considered to be so limited as for use with any particular structures alone. Moreover, although an exemplary tool system will be described to provide foundation for the present technology, it is to be understood that the present technology can be incorporated with any number of semiconductor processing chambers and tools that may benefit from some or all of the operations and systems to be described.

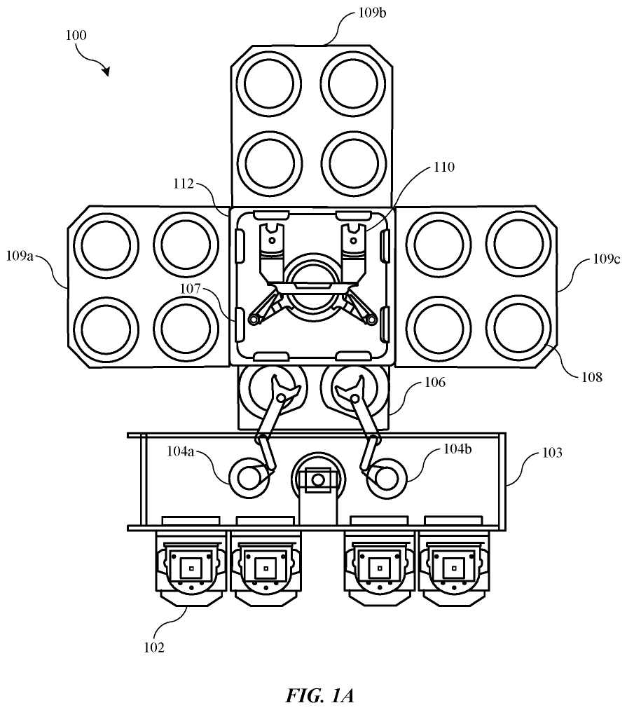

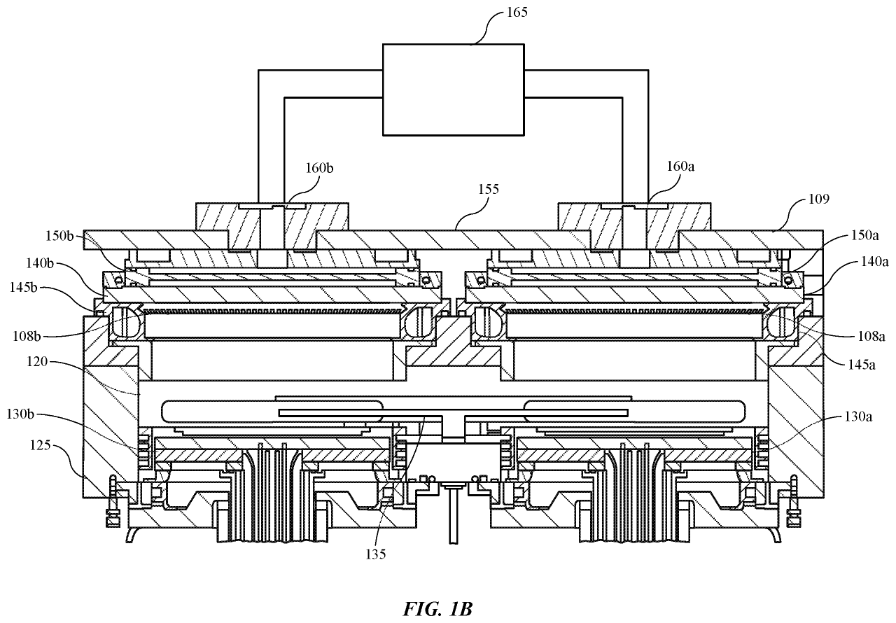

FIG. 1A shows a top plan view of one embodiment of a substrate processing tool or processing system 100 of deposition, etching, baking, and curing chambers according to some embodiments of the present technology. In the figure, a set of front-opening unified pods 102 supply substrates of a variety of sizes that are received within a factory interface 103 by robotic arms 104a and 104b and placed into a load lock or low pressure holding area 106 before being delivered to one of the substrate processing regions 108, positioned in chamber systems or quad sections 109a-c, which may each be a substrate processing system having a transfer region fluidly coupled with a plurality of processing regions 108. Although a quad system is illustrated, it is to be understood that platforms incorporating standalone chambers, twin chambers, and other multiple chamber systems are equally encompassed by the present technology. A second robotic arm 110 housed in a transfer chamber 112 may be used to transport the substrate wafers from the holding area 106 to the quad sections 109 and back, and second robotic arm 110 may be housed in a transfer chamber with which each of the quad sections or processing systems may be connected. Each substrate processing region 108 can be outfitted to perform a number of substrate processing operations including any number of deposition processes including cyclical layer deposition, atomic layer deposition, chemical vapor deposition, physical vapor deposition, as well as etch, pre-clean, anneal, plasma processing, degas, orientation, and other substrate processes.

Each quad section 109 may include a transfer region that may receive substrates from, and deliver substrates to, second robotic arm 110. The transfer region of the chamber system may be aligned with the transfer chamber having the second robotic arm 110. In some embodiments the transfer region may be laterally accessible to the robot. In subsequent operations, components of the transfer sections may vertically translate the substrates into the overlying processing regions 108. Similarly, the transfer regions may also be operable to rotate substrates between positions within each transfer region. The substrate processing regions 108 may include any number of system components for depositing, annealing, curing and/or etching a material film on the substrate or wafer. In one configuration, two sets of the processing regions, such as the processing regions in quad section 109a and 109b, may be used to deposit material on the substrate, and the third set of processing chambers, such as the processing chambers or regions in quad section 109c, may be used to cure, anneal, or treat the deposited films. In another configuration, all three sets of chambers, such as all twelve chambers illustrated, may be configured to both deposit and/or cure a film on the substrate.

As illustrated in the figure, second robotic arm 110 may include two arms for delivering and/or retrieving multiple substrates simultaneously. For example, each quad section 109 may include two accesses 107 along a surface of a housing of the transfer region, which may be laterally aligned with the second robotic arm. The accesses may be defined along a surface adjacent the transfer chamber 112. In some embodiments, such as illustrated, the first access may be aligned with a first substrate support of the plurality of substrate supports of a quad section. Additionally, the second access may be aligned with a second substrate support of the plurality of substrate supports of the quad section. The first substrate support may be adjacent to the second substrate support, and the two substrate supports may define a first row of substrate supports in some embodiments. As shown in the illustrated configuration, a second row of substrate supports may be positioned behind the first row of substrate supports laterally outward from the transfer chamber 112. The two arms of the second robotic arm 110 may be spaced to allow the two arms to simultaneously enter a quad section or chamber system to deliver or retrieve one or two substrates to substrate supports within the transfer region.

Any one or more of the transfer regions described may be incorporated with additional chambers separated from the fabrication system shown in different embodiments. It will be appreciated that additional configurations of deposition, etching, annealing, and curing chambers for material films are contemplated by processing system 100. Additionally, any number of other processing systems may be utilized with the present technology, which may incorporate transfer systems for performing any of the specific operations, such as the substrate movement. In some embodiments, processing systems that may provide access to multiple processing chamber regions while maintaining a vacuum environment in various sections, such as the noted holding and transfer areas, may allow operations to be performed in multiple chambers while maintaining a particular vacuum environment between discrete processes.

FIG. 1B shows a schematic cross-sectional elevation view of one embodiment of an exemplary processing tool, such as through a chamber system, according to some embodiments of the present technology. FIG. 1B may illustrate a cross-sectional view through any two adjacent processing regions 108 in any quad section 109. The elevation view may illustrate the configuration or fluid coupling of one or more processing regions 108 with a transfer region 120. For example, a continuous transfer region 120 may be defined by a transfer region housing 125. The housing may define an open interior volume in which a number of substrate supports 130 may be disposed. For example, as illustrated in FIG. 1A, exemplary processing systems may include four or more, including a plurality of substrate supports 130 distributed within the housing about the transfer region. The substrate supports may be pedestals as illustrated, although a number of other configurations may also be used. In some embodiments the pedestals may be vertically translatable between the transfer region 120 and the processing regions overlying the transfer region. The substrate supports may be vertically translatable along a central axis of the substrate support along a path between a first position and a second position within the chamber system. Accordingly, in some embodiments each substrate support 130 may be axially aligned with an overlying processing region 108 defined by one or more chamber components.

The open transfer region may afford the ability of a transfer apparatus 135, such as a carousel, to engage and move substrates, such as rotationally, between the various substrate supports. The transfer apparatus 135 may be rotatable about a central axis. This may allow substrates to be positioned for processing within any of the processing regions 108 within the processing system. The transfer apparatus 135 may include one or more end effectors that may engage substrates from above, below, or may engage exterior edges of the substrates for movement about the substrate supports. The transfer apparatus may receive substrates from a transfer chamber robot, such as robot 110 described previously. The transfer apparatus may then rotate substrates to alternate substrate supports to facilitate delivery of additional substrates.

Once positioned and awaiting processing, the transfer apparatus may position the end effectors or arms between substrate supports, which may allow the substrate supports to be raised past the transfer apparatus 135 and deliver the substrates into the processing regions 108, which may be vertically offset from the transfer region. For example, and as illustrated, substrate support 130a may deliver a substrate into processing region 108a, while substrate support 130b may deliver a substrate into processing region 108b. This may occur with the other two substrate supports and processing regions, as well as with additional substrate supports and processing regions in embodiments for which additional processing regions are included. In this configuration, the substrate supports may at least partially define a processing region 108 from below when operationally engaged for processing substrates, such as in the second position, and the processing regions may be axially aligned with an associated substrate support. The processing regions may be defined from above by a faceplate 140, as well as other lid stack components. In some embodiments, each processing region may have individual lid stack components, although in some embodiments components may accommodate multiple processing regions 108. Based on this configuration, in some embodiments each processing region 108 may be fluidly coupled with the transfer region, while being fluidly isolated from above from each other processing region within the chamber system or quad section.

In some embodiments the faceplate 140 may operate as an electrode of the system for producing a local plasma within the processing region 108. As illustrated, each processing region may utilize or incorporate a separate faceplate. For example, faceplate 140a may be included to define from above processing region 108a, and faceplate 140b may be included to define from above processing region 108b. In some embodiments the substrate support may operate as the companion electrode for generating a capacitively-coupled plasma between the faceplate and the substrate support. A pumping liner 145 may at least partially define the processing region 108 radially, or laterally depending on the volume geometry. Again, separate pumping liners may be utilized for each processing region. For example, pumping liner 145a may at least partially radially define processing region 108a, and pumping liner 145b may at least partially radially define processing region 108b. A blocker plate 150 may be positioned between a lid 155 and the faceplate 140 in embodiments, and again separate blocker plates may be included to facilitate fluid distribution within each processing region. For example, blocker plate 150a may be included for distribution towards processing region 108a, and blocker plate 150b may be included for distribution towards processing region 108b.

Lid 155 may be a separate component for each processing region, or may include one or more common aspects. In some embodiments, such as illustrated, lid 155 may be a single component defining multiple apertures 160 for fluid delivery to individual processing regions. For example, lid 155 may define a first aperture 160a for fluid delivery to processing region 108a, and lid 155 may define a second aperture 160b for fluid delivery to processing region 108b. Additional apertures may be defined for additional processing regions within each section when included. In some embodiments, each quad section 109—or multi-processing-region section that may accommodate more or less than four substrates, may include one or more remote plasma units 165 for delivering plasma effluents into the processing chamber. In some embodiments individual plasma units may be incorporated for each chamber processing region, although in some embodiments fewer remote plasma units may be used. For example, as illustrated a single remote plasma unit 165 may be used for multiple chambers, such as two, three, four, or more chambers up to all chambers for a particular quad section. Piping may extend from the remote plasma unit 165 to each aperture 160 for delivery of plasma effluents for processing or cleaning in embodiments of the present technology.

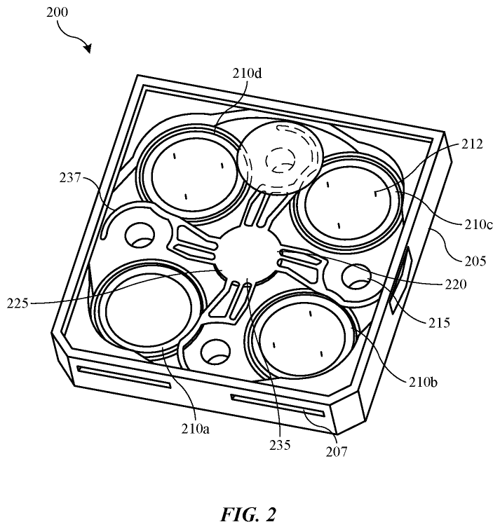

As noted, processing system 100, or more specifically quad sections or chamber systems incorporated with processing system 100 or other processing systems, may include transfer sections positioned below the processing chamber regions illustrated. FIG. 2 shows a schematic isometric view of a transfer section of an exemplary chamber system 200 according to some embodiments of the present technology. FIG. 2 may illustrate additional aspects or variations of aspects of the transfer region 120 described above, and may include any of the components or characteristics described. The system illustrated may include a transfer region housing 205 defining a transfer region in which a number of components may be included. The transfer region may additionally be at least partially defined from above by processing chambers or processing regions fluidly coupled with the transfer region, such as processing chamber regions 108 illustrated in quad sections 109 of FIG. 1A. A sidewall of the transfer region housing may define one or more access locations 207 through which substrates may be delivered and retrieved, such as by second robotic arm 110 as discussed above. Access locations 207 may be slit valves or other sealable access positions, which include doors or other sealing mechanisms to provide a hermetic environment within transfer region housing 205 in some embodiments. Although illustrated with two such access locations 207, it is to be understood that in some embodiments only a single access location 207 may be included, as well as access locations on multiple sides of the transfer region housing. It is also to be understood that the transfer section illustrated may be sized to accommodate any substrate size, including 200 mm, 300 mm, 450 mm, or larger or smaller substrates, including substrates characterized by any number of geometries or shapes.

Within transfer region housing 205 may be a plurality of substrate supports 210 positioned about the transfer region volume. Although four substrate supports are illustrated, it is to be understood that any number of substrate supports are similarly encompassed by embodiments of the present technology. For example, greater than or about three, four, five, six, eight, or more substrate supports 210 may be accommodated in transfer regions according to embodiments of the present technology. Second robotic arm 110 may deliver a substrate to either or both of substrate supports 210a or 210b through the accesses 207. Similarly, second robotic arm 110 may retrieve substrates from these locations. Lift pins 212 may protrude from the substrate supports 210, and may allow the robot to access beneath the substrates. The lift pins may be fixed on the substrate supports, or at a location where the substrate supports may recess below, or the lift pins may additionally be raised or lowered through the substrate supports in some embodiments. Substrate supports 210 may be vertically translatable, and in some embodiments may extend up to processing chamber regions of the substrate processing systems, such as processing chamber regions 108, positioned above the transfer region housing 205.

The transfer region housing 205 may provide access 215 for alignment systems, which may include an aligner that can extend through an aperture of the transfer region housing as illustrated and may operate in conjunction with a laser, camera, or other monitoring device protruding or transmitting through an adjacent aperture, and that may determine whether a substrate being translated is properly aligned. Transfer region housing 205 may also include a transfer apparatus 220 that may be operated in a number of ways to position substrates and move substrates between the various substrate supports. In one example, transfer apparatus 220 may move substrates on substrate supports 210a and 210b to substrate supports 210c and 210d, which may allow additional substrates to be delivered into the transfer chamber. Additional transfer operations may include rotating substrates between substrate supports for additional processing in overlying processing regions.

Transfer apparatus 220 may include a central hub 225 that may include one or more shafts extending into the transfer region. Coupled with the shaft may be an end effector 235. End effector 235 may include a plurality of arms 237 extending radially or laterally outward from the central hub. Although illustrated with a central body from which the arms extend, the end effector may additionally include separate arms that are each coupled with the shaft or central hub in various embodiments. Any number of arms may be included in embodiments of the present technology. In some embodiments a number of arms 237 may be similar or equal to the number of substrate supports 210 included in the chamber. Hence, as illustrated, for four substrate supports, transfer apparatus 220 may include four arms extending from the end effector. The arms may be characterized by any number of shapes and profiles, such as straight profiles or arcuate profiles, as well as including any number of distal profiles including hooks, rings, forks, or other designs for supporting a substrate and/or providing access to a substrate, such as for alignment or engagement.

The end effector 235, or components or portions of the end effector, may be used to contact substrates during transfer or movement. These components as well as the end effector may be made from or include a number of materials including conductive and/or insulative materials. The materials may be coated or plated in some embodiments to withstand contact with precursors or other chemicals that may pass into the transfer chamber from an overlying processing chamber.

Additionally, the materials may be provided or selected to withstand other environmental characteristics, such as temperature. In some embodiments, the substrate supports may be operable to heat a substrate disposed on the support. The substrate supports may be configured to increase a surface or substrate temperature to temperatures greater than or about 100° C., greater than or about 200° C., greater than or about 300° C., greater than or about 400° C., greater than or about 500° C., greater than or about 600° C., greater than or about 700° C., greater than or about 800° C., or higher. Any of these temperatures may be maintained during operations, and thus components of the transfer apparatus 220 may be exposed to any of these stated or encompassed temperatures. Consequently, in some embodiments any of the materials may be selected to accommodate these temperature regimes, and may include materials such as ceramics and metals that may be characterized by relatively low coefficients of thermal expansion, or other beneficial characteristics.

Component couplings may also be adapted for operation in high temperature and/or corrosive environments. For example, where end effectors and end portions are each ceramic, the coupling may include press fittings, snap fittings, or other fittings that may not include additional materials, such as bolts, which may expand and contract with temperature, and may cause cracking in the ceramics. In some embodiments the end portions may be continuous with the end effectors, and may be monolithically formed with the end effectors. Any number of other materials may be utilized that may facilitate operation or resistance during operation, and are similarly encompassed by the present technology. The transfer apparatus 220 may include a number of components and configurations that may facilitate the movement of the end effector in multiple directions, which may facilitate rotational movement, as well as vertical movement, or lateral movement in one or more ways with the drive system components to which the end effector may be coupled.

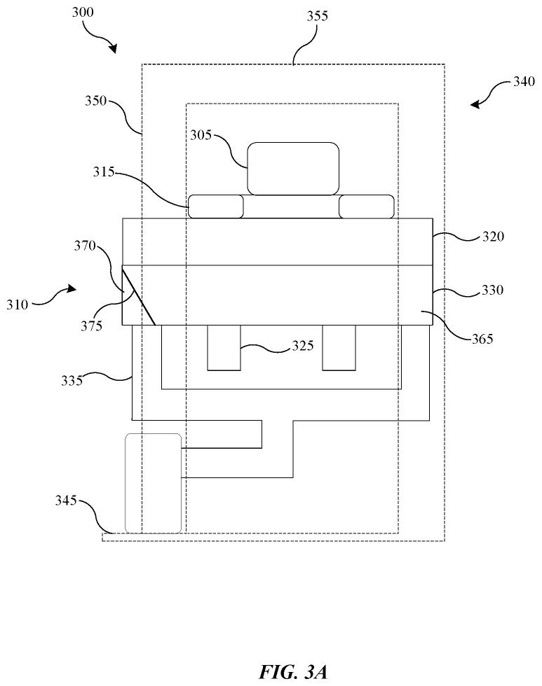

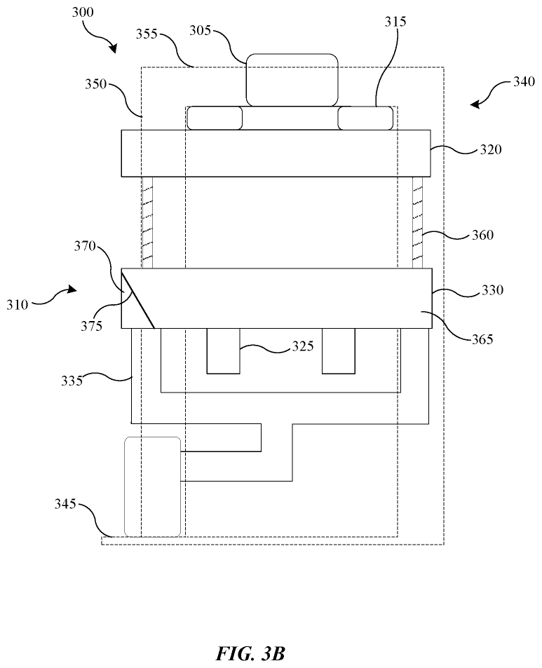

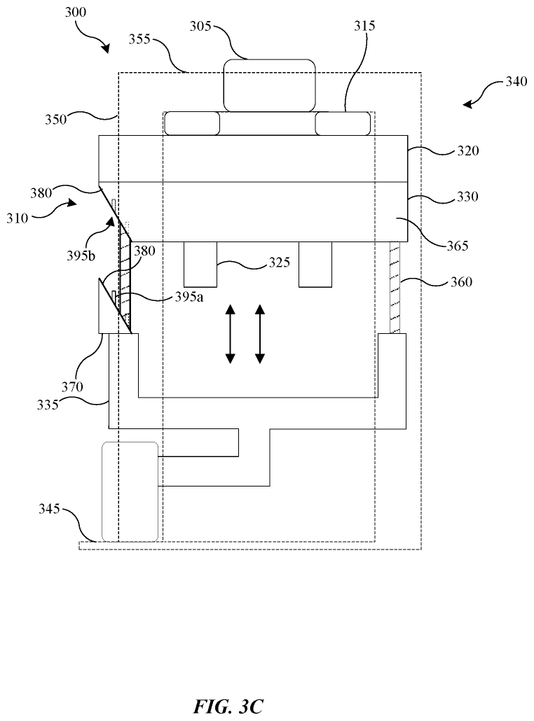

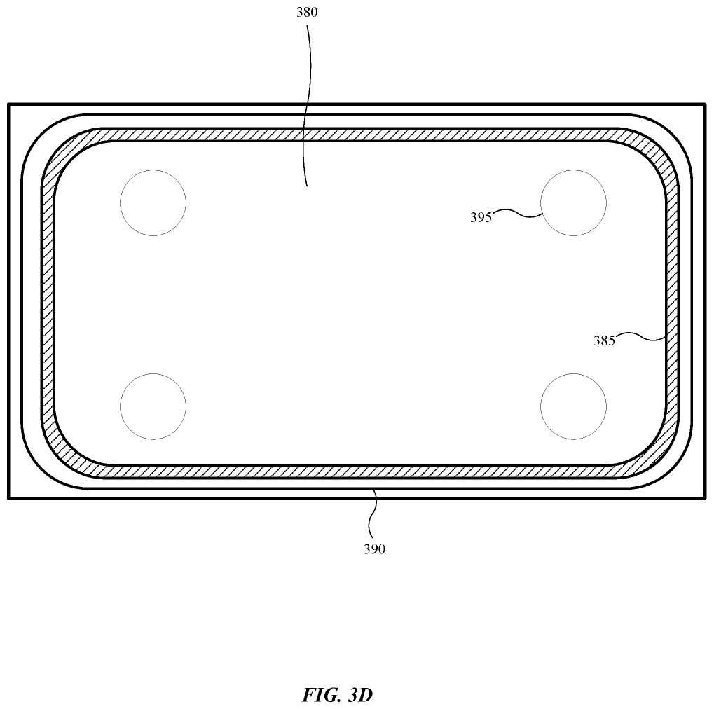

FIGS. 3A-3C show schematic side elevation views of an exemplary processing system 300 according to some embodiments of the present technology. FIGS. 3A-3C may illustrate further details relating to components in systems 100 and 200. System 300 is understood to include any feature or aspect of systems 100 or 200 discussed previously in some embodiments. The system 300 may be used to perform semiconductor processing operations, such as deposition, removal, and cleaning operations. System 300 may show a partial view of the chamber components being discussed and that may be incorporated in a semiconductor processing system. Any aspect of system 300 may also be incorporated with other processing chambers or systems as will be readily understood by the skilled artisan.

System 300 may include a remote plasma unit 305 for delivering plasma effluents into a processing chamber body 310 via one or more isolation valves 315. The remote plasma unit 305 and isolation valves 315 may be supported atop a lid assembly 320. Lid assembly 320 may include a lid and a lid stack, which may include a number of lid stack components that may facilitate flow of precursors through the chamber system. For example, the lid stack may include, without limitation, a liner, a pumping liner positioned atop the liner, a faceplate, a blocker plate seated on the faceplate, a gas box that may be positioned above the blocker plate, and/or a number of lid plates. The chamber body 310 may include a transfer region housing 330 that defines a transfer region. Transfer region housing 330 may be similar to those described herein, such as transfer region housing 125 and 205. For example, the transfer region housing 330 may define an open interior volume in which a transfer apparatus and/or a number of substrate supports may be disposed. The transfer region housing 330 may also define at least a portion of one or more processing regions. Each substrate support within the transfer region housing 330 may have a shaft 325 that may extend through a bottom of the transfer region housing 330 and/or other portion of the chamber body 310. System 300 may also include a number of forelines 335, which may be used to direct fluid flow from an exhaust of the processing chamber. The forelines 335 may be coupled with the lid stack and/or the chamber body 310. For example, in one particular embodiment, the forelines 335 may be fluidly coupled with a gas outlet of the pumping liner of the lid stack. In some embodiments, bellows may be disposed between the forelines 335 and the lid stack and/or chamber body 310 that help compensate for misalignment and/or movement of the lid stack and/or chamber body 310 relative to the forelines 335.

In some embodiments, the system 300 may be self-supporting, while in other embodiments the system 300 may also include a frame 340, which may include or be coupled with a base 345 that supports various components of the system 300. Frame 340 may include sidewalls 350 and a top 355, which may define an outer housing or support of the system 300. The sidewalls 350 may extend upward from the base 345 and may be coupled with the chamber body 310 and the lid assembly 320. For example, the chamber body 310 and/or the lid assembly 320 may be mounted on or otherwise supported by the sidewalls 350. In some embodiments, to facilitate more efficient shipping, the sidewalls 350 of the frame 340 may telescope. For example, the sidewalls 350 may include telescoping arms, rods, and/or other members that are extendable and contractible between a shortened position and an extended position to adjust a height of the top 355 of the frame. For storage and/or shipping, the sidewalls 350 may be contracted to reduce the height of the frame 340. When the system 300 is installed and operational, the sidewalls 350 may be extended to increase the height of the frame 340 to provide sufficient space for semiconductor processing operations and/or performing maintenance on the system 300.

To facilitate servicing of system 300, one or more components of the system 300 may be moved relative to one another to provide access to the interior of the system 300. For example, at least a portion of the lid assembly 320 may be lifted upward off of the chamber body 310 to provide access to components of the chamber body 310 and/or the lid stack. In some embodiments, the entire lid assembly 320 may be lifted upwards to provide access to the chamber 310. In some embodiments, only a portion of the lid assembly, such as the lid and/or one or more components of the lid stack, may be lifted, thereby providing access to one or more components of the lid stack. As illustrated in FIG. 3B, one or more lifting mechanisms 360 may be coupled with the lid assembly 320 to raise and lower all or a portion of the lid assembly 320. In some embodiments, the lifting mechanisms 360 may be coupled with the frame 340 and may enable all or part of the lid assembly 320 to be raised and lowered along the sidewalls 350 of the frame 340. Various lifting mechanisms 360 may be used to raise and lower the lid assembly 320. For example, the lifting mechanisms 360 may include chain lifts, rack and pinion lifts, worm gear lifts (such as worm gear jacks and/or worm gear hoists driven by rotational actuators), threaded rod lifts, and/or other linear actuators. The lid assembly, or portion thereof, may be lifted between an operational position and a maximum elevated position to provide sufficient clearance for a service operation. The maximum elevated position may enable the elevation of a bottom of the lid assembly (or portion thereof) by a distance of greater than or about 6 inches, greater than or about 9 inches, greater than or about 12 inches, greater than or about 15 inches, greater than or about 18 inches, greater than or about 21 inches, greater than or about 24 inches, or more.

In some embodiments, after lifting the lid assembly 320, a portion of the transfer region body 330 may be moved relative to the lower components of the system 300, such as the forelines 335. As best illustrated in FIG. 3C, the transfer region housing 330 may include a first portion 365 and a second portion 370. The second portion 370 may be smaller than the first portion 365 and may remain at a fixed location relative to the frame 340. The first portion 365 may be lifted upward away from the second portion 370 and forelines 335 to provide access to lower components of the system 300. The first portion 365 may be lifted using the lifting mechanisms 360 used to lift the lid assembly 320 and/or may include dedicated lifting mechanisms. The first portion 365 of the transfer region housing 330 may be lifted independently of the lid assembly 320 and/or may be lifted in unison with the lid assembly 320. The first portion 365 of the transfer region housing 330 may be lifted between an operational position and a maximum elevated position to provide sufficient clearance for a service operation. Oftentimes, the maximum elevated position may be limited by the elevated height of the lid assembly 320. For example, the first portion 365 may be elevated by a distance of greater than or about 6 inches, greater than or about 9 inches, greater than or about 12 inches, greater than or about 15 inches, greater than or about 18 inches, greater than or about 21 inches, greater than or about 24 inches, or more.

To facilitate the proper alignment and sealing of an interface 375 (as shown in FIGS. 3A and 3B) between the first portion 365 and the second portion 370, mating faces 380 of the first portion 365 and the second portion 370 may be angled relative to vertical. For example, an angle of the mating faces 380 may be between about 10 degrees and about 80 degrees, between about 20 degrees and about 70 degrees, between about 30 degrees and 60 degrees, or between about 40 degrees and 50 degrees relative to vertical, with steeper angles providing greater repeatability and reducing abrasive wear between the mating faces 380. To help seal the interior of the transfer region housing 330 when the first portion 365 and the second portion 370 are mated in an operational configuration (with mating faces 380 abutting one another to form interface 375), one or both of the mating faces 380 includes a sealing element 385 as shown in FIG. 3D, which illustrates a plan view of one of the mating faces 380. The sealing element 385 may be an O-ring, gasket, and/or other sealing member that may be compressed between the two mating faces 380 to seal the transfer region housing 330. In some embodiments, one or both of the mating faces 380 may include a radio frequency (RF) gasket 390 that shields the transfer region housing 330 from RF radiation from outside the transfer region housing 330 when the mating faces 380 are joined to form the interface 375 when in the operational configuration.

To further ensure that the first portion 365 and second portion 370 are properly aligned when in the operational configuration, each mating face 380 may include a number of alignment features 395 that are manufactured with precise tolerances to ensure proper alignment. For example, a first one of the mating faces 380 may include a number of alignment pins 395a, such as bullet pins or other linear members, that project vertically from the mating face 380. A second one of the mating faces 380 may define a number of apertures 395b that are aligned with and sized to receive the alignment pins 395a when the mating faces 380 are joined to form the interface 375 in the operational configuration. In some embodiments, the apertures 395b may include bushings and/or sleeves formed from metal and/or other hard material which prevent the material forming the apertures 395b from wearing away due to sliding contact with the alignment pins 395a. While shown with alignment pins 395a protruding from the mating face 380 of the second portion 370 and apertures 395b being defined in the mating face 380 of the first portion 365, it will be appreciated that an opposite arrangement may be utilized. Additionally, in some embodiments each mating face 380 may have one or more alignment pins 395a and one or more apertures 395b, with positions of pins 395a on one mating face 380 corresponding to positions of apertures 395b on the other mating face 380.

While not shown, it will be appreciated that alignment features may be positioned on other components to help with alignment of the system 300. For example, a top surface of the transfer region housing 330 and a bottom surface of the lid assembly 320 may include corresponding alignment features to assist with proper alignment with the components as the lid assembly 320 is lowered onto the transfer region housing 330. Similarly, alignment features may be included in between various movable components of the lid assembly 320, such as the lid and/or lid stack components.

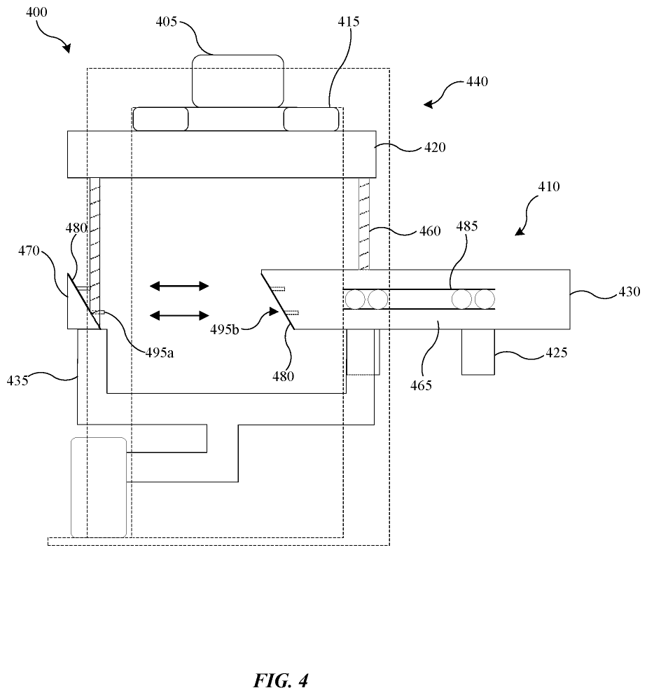

FIG. 4 shows a schematic side elevation view of an exemplary processing system 400 according to some embodiments of the present technology. FIG. 4 may illustrate further details relating to components in systems 100, 200, and 300. System 400 is understood to include any feature or aspect of systems 100, 200, and 300 discussed previously in some embodiments. The system 400 may be used to perform semiconductor processing operations, such as deposition, removal, and cleaning operations. System 400 may show a partial view of the chamber components being discussed and that may be incorporated in a semiconductor processing system. Any aspect of system 300 may also be incorporated with other processing chambers or systems as will be readily understood by the skilled artisan.

System 400 may include a remote plasma unit 405 for delivering plasma effluents into a processing chamber body 410 via one or more isolation valves 415. The remote plasma unit 405 and isolation valves 415 may be supported atop a lid assembly 420. Lid assembly 420 may include a lid and a lid stack, which may include a number of lid stack components that may facilitate flow of precursors through the chamber system. The chamber body 410 may include a transfer region housing 430 that defines a transfer region. Transfer region housing 430 may be similar to those described herein, such as transfer region housing 125, 205, and 330 and may include a number of substrate supports that each have a shaft 425 that may extend through a bottom of the transfer region housing 430 and/or other portion of the chamber body 410. System 400 may also include a number of forelines 435, which may be used to direct fluid flow toward an exhaust of the processing chamber. The system 400 may also include a frame 440, which may be similar to frame 340 described above.

As illustrated, one or more lifting mechanisms 460 may be used to lift the lid assembly 420 (or portion thereof) in a manner similar to that described in relation to FIGS. 3A and 3B. After lifting the lid assembly 420, a portion of the transfer region housing 430 may be slid at least partially out of vertical alignment with the lid assembly 420 and the frame 440. For example, the transfer region housing 430 may include a first portion 465 and a second portion 470. The first portion 465 may be slid laterally away from the second portion 470 (which remains stationary) to provide access to lower components of the system 400. The first portion 465 may be coupled with a slide 485 that provides mechanical advantage to facilitate smooth horizontal movement of the first portion 465 such that all or a portion of the first portion 465 extends beyond a periphery of the frame 440. For example, the slide 485 may include a slidable tray, a roller track assembly, a telescopic slide, a glide track, and/or other sliding mechanism. In some embodiments, the slide 485 may be coupled between the first portion 465 and the frame 440 to enable the first portion 465 to slide in and out relative to the frame 440. By sliding, rather than lifting, the transfer region housing 430, the power requirements of the lifting mechanisms 460 used to lift the lid assembly 420 may be reduced, as there is no need to account for the substantial weight of the transfer region housing 430 and components housed therein.

Mating faces 480 of the first portion 465 and the second portion 470 may be vertical and/or may be angled relative to vertical. For example, an angle of the mating faces 480 may be between about 10 degrees and about 80 degrees, between about 20 degrees and about 70 degrees, between about 30 degrees and 60 degrees, or between about 40 degrees and 50 degrees relative to vertical. One or both of the mating faces may include a sealing element and/or RF gasket to protect the interior of the transfer region housing 430 when in an operational configuration, and maintain an RF grounding path about the system.

To facilitate the proper alignment and sealing of an interface (similar to interface 375 shown in FIGS. 3A and 3B) between the first portion 465 and the second portion 470, each mating face 480 may include a number of alignment features 495 that are manufactured with precise tolerances to ensure proper alignment. For example, each mating face 480 may include one or more horizontally-oriented alignment pins 495a and/or one or more apertures 495b, with positions of pins 495a on one mating face 480 at positions that correspond to apertures 495b on the other mating face 480.

While not shown, it will be appreciated that alignment features may be positioned on other components to help with alignment of the system 400. For example, a top surface of the transfer region housing 430 and a bottom surface of the lid assembly 420 may include corresponding alignment features to assist with proper alignment with the components as the lid assembly 420 is lowered onto the transfer region housing 430. Similarly, alignment features may be included in between various movable components of the lid assembly 420, such as the lid and/or lid stack components.

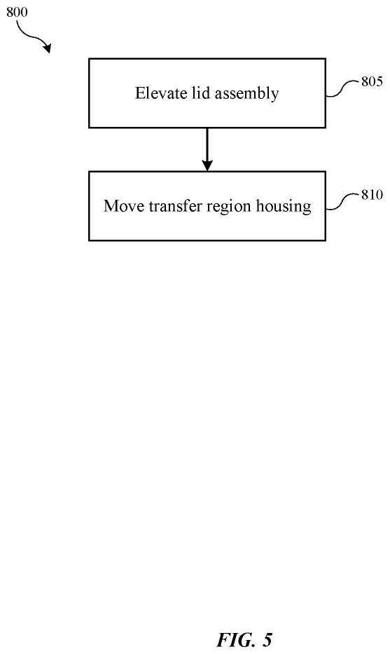

FIG. 5 shows operations of an exemplary method 500 of providing access to an interior of a semiconductor processing system according to some embodiments of the present technology. The method may be performed in a variety of processing chambers, including processing system 100, 200, 300, and 400 described above, which may include transfer region housings having disengageable first and second portions according to embodiments of the present technology. Method 500 may include a number of optional operations, which may or may not be specifically associated with some embodiments of methods according to the present technology.

Method 500 may include a method that may include optional operations prior to initiation of method 500, or the method may include additional operations. For example, method 500 may include operations performed in different orders than illustrated. In some embodiments, method 500 may include elevating, using one or more lift mechanisms, at least a portion of a lid assembly of a substrate processing system relative to a base of the substrate processing system at operation 505. For example, the lid assembly (or portion thereof) may be lifted off of a top of a chamber body of the processing system. At operation 510, a first portion of a transfer region housing of a chamber body of the substrate processing system may be moved out of engagement with a second portion of the transfer region housing. For example, the first portion of the transfer region housing may be lifted in a vertical direction relative to the base and the second portion. In some embodiments, the first portion of the transfer region housing may be moved in the vertical direction in unison with elevation of the lid. In other embodiments, rather than elevating the first portion of the transfer region housing, the transfer region housing may be slid and/or otherwise moved in a horizontal direction away from the second portion to provide access to the interior of the substrate processing system. When in an operational configuration, the first portion and the second portion mate with one another to form a sealed and complete transfer region housing. In some embodiments, prior to moving the transfer region housing, additional optional operations may be performed including decoupling foreline connections, separating fluid line connections, or any other operation to separate stationary components from moving components.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a heater” includes a plurality of such heaters, and reference to “the aperture” includes reference to one or more apertures and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

What is claimed is:

1. A substrate processing system, comprising:
a base;
a chamber body comprising a transfer region housing that defines a transfer region, wherein the transfer region housing comprises a first portion and a second portion;
a lid assembly positioned atop the chamber body, the lid assembly comprising a lid and a lid stack; and
one or more lift mechanisms that elevate the first portion of the transfer region housing and at least a portion of the lid assembly relative to the base, wherein:
the first portion and the second portion mate with one another when the transfer region housing is in an operational configuration; and
the first portion and the second portion are separated when the first portion of the transfer region housing is elevated.

2. The substrate processing system of claim 1, wherein:
an interface between the first portion and the second portion comprises a sealing element that seals an interior of the transfer region housing when the transfer region housing is in the operational configuration.

3. The substrate processing system of claim 1, wherein:
an interface between the first portion and the second portion comprises a radio frequency gasket.

4. The substrate processing system of claim 1, wherein:
at an interface between the first portion and the second portion, faces of each of the first portion and the second portion are angled relative to vertical.

5. The substrate processing system of claim 1, wherein:
an angle of the faces of each of the first portion and the second portion is between about 10 degrees and about 80 degrees relative to vertical.

6. The substrate processing system of claim 1, wherein:
one of the first portion and the second portion comprises one or more alignment pins and the other of the first portion and the second portion defines one or more apertures that receive the one or more alignment pins when the first portion and the second portion are in the operational configuration.

7. The substrate processing system of claim 6, wherein:
each of the one or more apertures is lined with a bushing.

8. The substrate processing system of claim 1, wherein:
the transfer region housing and the at least the portion of the lid assembly are elevatable independently of one another by the one or more lift mechanisms.

9. The substrate processing system of claim 1, wherein:
the one or more lift mechanisms comprise a worm gear lift that is driven by a rotational actuator.

10. The substrate processing system of claim 1, further comprising:
a frame that is coupled with each of the base, the chamber body, and the lid assembly, wherein a top of the frame telescopes between a first height and a second height.

11. A substrate processing system, comprising:
a base;
a chamber body comprising a transfer region housing that defines a transfer region, wherein the transfer region housing comprises a first portion and a second portion;
a lid assembly positioned atop the chamber body, the lid assembly comprising a lid and a lid stack;
one or more lift mechanisms that elevate at least a portion of the lid assembly relative to the base; and
a slide that slides the first portion of the transfer region housing at least partially out of vertical alignment with the lid assembly and the base, wherein:
the first portion and the second portion mate with one another when the transfer region housing is in an operational configuration; and
the first portion and the second portion are separated when the first portion of the transfer region housing is slid at least partially out of vertical alignment with the lid assembly and the base.

12. The substrate processing system of claim 11, wherein:
at an interface between the first portion and the second portion, faces of each of the first portion and the second portion are vertical.

13. The substrate processing system of claim 11, wherein:
at an interface between the first portion and the second portion, faces of each of the first portion and the second portion are angled relative to vertical.

14. The substrate processing system of claim 11, wherein:
an interface between the first portion and the second portion comprises a sealing element that seals an interior of the transfer region housing when the transfer region housing is in the operational configuration.

15. The substrate processing system of claim 11, further comprising:
a frame coupled with the base, wherein the slide comprises a roller track assembly that slidingly couples the first portion of the transfer region housing with the frame.

16. The substrate processing system of claim 11, further comprising:
a frame that is coupled with each of the base, the chamber body, and the lid assembly, wherein a top of the frame telescopes between a first height and a second height.

17. The substrate processing system of claim 11, wherein:
one of the first portion and the second portion comprises one or more alignment pins and the other of the first portion and the second portion defines one or more apertures that receive the one or more alignment pins when the first portion and the second portion are in the operational configuration.

18. The substrate processing system of claim 11, wherein:
one of a top surface of the chamber body and a bottom surface of the lid assembly comprises one or more alignment pins and the other of the top surface and the bottom surface defines one or more apertures that receive the one or more alignment pins when the lid assembly is positioned atop the chamber body.

19. A method of providing access to an interior of a substrate processing system, comprising:
elevating, using one or more lift mechanisms, at least a portion of a lid assembly of a substrate processing system relative to a base of the substrate processing system, wherein the lid assembly comprises a lid and a lid stack; and
moving a first portion of a transfer region housing of a chamber body of the substrate processing system out of engagement with a second portion of the transfer region housing in a vertical direction or a horizontal direction to provide access to the interior of the substrate processing system, wherein the first portion and the second portion mate with one another when the transfer region housing is in an operational configuration.

20. The method of providing access to the interior of the substrate processing system of claim 19, wherein:
the first portion of the transfer region housing is moved in the vertical direction in unison with elevation of the lid.
